(19) United States
(12) Patent Application Publication
(10) Pub. No.: US 2022/0244332 A1
(43) Pub. Date: Aug. 4, 2022

(54) INTELLIGENT CONTROL SYSTEM AND METHODS FOR IMPROVING ENERGY EFFICIENCY OF A MAGNETIC RESONANCE IMAGING SYSTEM

(71) Applicant: SYNAPTIVE MEDICAL INC., TORONTO (CA)

(72) Inventors: Jeff Alan STAINSBY, Toronto (CA); Chad Tyler HARRIS, Toronto (CA); Alexander Gyles PANTHER, Toronto (CA)

(21) Appl. No.: 17/659,719

(22) Filed: Apr. 19, 2022

Related U.S. Application Data
(63) Continuation of application No. 63/201,471, filed on Apr. 30, 2021.
Application No. 63/201,471 is a continuation of application No. 17/162,051, filed on Jan. 29, 2021.

(51) Int. Cl. G01R 33/3815; G01R 33/38; H01F 6/04

(52) U.S. Cl. CPC G01R 33/3815; H01F 6/04; G01R 33/3804

(57) ABSTRACT

An intelligent control system (S) and methods (M, M1, M2) for dynamically controlling components of an MRI system (10), the intelligent control system (S) involving a processor (700), configurable to: determine a current-use state of each component; optimize energy usage among the components based on the current-use state of each component, whereby an optimal energy usage is provided; alter an energy consumption profile of each component based on the optimal energy usage, whereby an altered energy consumption for each component is provided; automatically activate power to each component based on the altered energy consumption when the MRI system (10) is to be operated; and automatically deactivate power to each component based on the altered energy consumption when the MRI system (10) is not to be operated, whereby the MRI system (10) is automatically operable when needed and inoperable when not needed, continually powering the components is eliminated, and an average energy consumption of the MRI system (10) is reduced over its lifespan.

### CROSS-REFERENCE TO RELATED APPLICATION(S)

This document is a nonprovisional application claiming the benefit of, and priority to, U.S. Provisional Patent Application Ser. No. 63/201,471, entitled “ENERGY EFFICIENT MAGNETIC RESONANCE IMAGING SYSTEM,” filed on Apr. 30, 2021, and U.S. Nonprovisional patent application Ser. No. 17/162,051, entitled “MAGNETIC RESONANCE IMAGING SYSTEM AND METHOD FOR RAPID SHUTDOWN AND RECHARGE OF A SUPERCONDUCTING MAGNET,” filed on Jan. 29, 2021, U.S all of which are hereby incorporated by reference herein in their entirety.

### FIELD

Generally, the present disclosure relates to magnetic resonance imaging (MRI). More specifically, the present disclosure relates to power consumption in MRI. Even more specifically, the present disclosure relates to a system for improving power consumption in MRI.

### BACKGROUND

In the related art, MRI systems typically utilize one of two magnet assembly types to generate a strong main magnetic field used for imaging. A first type of magnet assembly type generates the main magnetic field by using permanent magnets. This first magnet assembly type is used less than the second magnet assembly type as the magnetic field strengths that can be achieved with the first magnet assembly type is limited. Moreover, the first magnet assembly type tends to be extremely heavy and is sensitive to temperature fluctuations; and permanent magnets cannot be switch-off. Thus, removing the magnetic field is impossible by using the first magnet assembly type. The second type of MRI system generates the main magnetic field by using a superconducting electromagnet. Using the superconducting magnet allows high current densities through conductors of the superconducting electromagnet without power dissipation, which, in turn, enables achieving high magnetic field strengths. For the electromagnet to be superconducting, the magnet coils thereof must be cooled to extremely low temperatures, e.g., about 4 Kelvin (K). One related art method for cooling the magnet coils to this low temperature, e.g., about 4 K, is performed by immersing the conductors in a liquid cryogen bath.

These related art MRI systems, having superconducting electromagnets, tend to be expensive due to the high cost of liquid cryogens, e.g., liquid helium, for the liquid cryogen bath. Furthermore, rapidly switching-on or switching-off the magnetic fields, generated by these superconducting electromagnets, is difficult. For example, rapidly switching-off the magnetic field (referred herein as a “quench”) typically requires heating the magnet coils so that a resistance is developed that can dissipate stored energy. This resistance produces heat, causing the liquid cryogen to boil, thereby rapidly converting the liquid cryogen to a gas, thereby eviscerating the cooling capability of the related art MRI system, and thereby eviscerating the magnetic field generated by the magnet coils. However, current is not restorable in the magnetic coils; and the magnet field cannot be regenerated until the liquid cryogen is replaced and the magnet coils are cooled to superconducting temperatures (a process that normally involves multiple days and significant expense). Furthermore, a risk of damage to, or displacement from ideal position of, the superconducting magnet coils exists during the rapid heating. The consequences of damage to the magnet coils can be as extreme as requiring complete replacement after a quench. Alternatively, current can be removed or added to superconducting electromagnets very slowly without heating to a boiling point of the liquid cryogen. In these situations, many hours are required to completely add or remove the current, thereby rendering infeasible rapidly switching-on or switching-off the magnetic fields, e.g., as would be needed in an emergency shutdown.

Other challenges experienced in the related art MRI systems include attraction of large metallic objects, such as oxygen tank, due to the strong magnetic field, wherein personnel can be accidentally physically “pinned” to the magnet by such large metallic objects, and wherein the magnet needs to be rapidly switched-off (but cannot be due to limitations in the related art MRI systems). Traditional related art superconducting magnets have implemented a mechanism in an attempt to rapidly switch-off the magnetic field in an emergency situation by “quenching” the magnet in the manner as described in this background section; however, all liquid cryogens are boiled-off very rapidly. Additionally, a further challenge is that quenching the magnet requires a time consuming and expensive replacement of the liquid cryogens before the magnetic field can be reestablished.

Although related art seeks improved imaging performance, such related art MRI scanners use many subsystems, such as gradient amplifiers, radio-frequency (RF) amplifiers, cooling systems, and high-performance computers, having high energy consumption demands. Estimates of per-exam energy usage for such related art MRI scanners are as high as 5 kWh to 20 kWh with daily consumption greater than 500 kWh. Such related art MRI scanners operate with an active “ready-to-scan” state and have a higher energy consumption than when they are operating in a defined powered-off state. Even in such a defined powered-off state, not all the subsystems are necessarily placed in the most energy efficient state. Furthermore, “powered-off” states may be limited, e.g., accounting for approximately only one-third of a day. While the related art has explored the current energy footprint of related art MRI scanners and the potential energy consumption reduction by using known methods, little improvement has actually been accomplished to actually reduce the energy consumption reduction for the related art MRI scanners and to actually reduce the associated operational costs arising from high energy consumption. Also, related art MRI systems continuously power scanner subcomponents so that the scanner is always ready to scan, even at times when it is not intended to scan.

Thus, a long-felt need exists in the related art for addressing challenges, such as an inability to rapidly switch-on and switch-off power to a superconducting electromagnet of an MRI system, an undue need for continually powering the subcomponents of an MRI system so that the MRI scanner is always ready to scan, even when the MRI scanner is not about to scan, and a lack of intelligent control of the subcomponents of an MRI system.

### SUMMARY

In addressing at least some of the challenges in the related art, an intelligent control system and methods are provided for dynamically controlling a plurality of components of an MRI system, in accordance with embodiments of the present disclosure. The intelligent control system and methods of the present disclosure involve a processor, configurable by a set of executable instructions storable in relation to a non-transient memory device, to at least one of automatically activate power and automatically deactivate power to plurality of components of the MRI system based on an optimal energy usage among the plurality of components of the MRI system to alter an energy consumption profile of each component of the plurality of components by determining a current-use state of each component of the plurality of components, whereby the MRI system is automatically operable when needed and inoperable when not needed, and whereby continually powering plurality of components is eliminated, and whereby an average energy consumption of the MRI system is reduced over its lifespan. The plurality of components comprise at least one of a superconducting electromagnet and an MRI scanner; and the plurality of components further comprise at least one of a gradient amplifier, a radio-frequency (RF) amplifier, a cooling system, and a high-performance computer.

In accordance with an embodiment of the present disclosure, an MRI system comprises a set of magnet coils for generating a magnetic field. The set of magnet coils comprise a superconducting material. The system further includes a mechanical cryocooler in thermal contact with the set of magnet coils and operable to reduce and maintain a temperature of the set of magnet coils below a transition temperature of the superconducting material and an energy storage device coupled with the set of magnet coils and configured to receive and store energy dissipated from the set of magnet coils during a rapid shutdown of the set of magnet coils.

In accordance with an embodiment of the present disclosure, a method of rapidly shutting-down and rapidly recharging a superconducting magnet comprises dissipating energy from a set of magnet coils in the superconducting magnet into an energy storage device coupled with the set of magnet coils based on a rapid shutdown condition, storing the dissipated energy in the energy storage device, determining a status of the rapid shutdown condition, and recharging the set of magnet coils using the energy stored in the energy storage device based on the status of the rapid shutdown condition.

In accordance with an embodiment of the present disclosure, a system for rapidly shutting-down and rapidly recharging a superconducting magnet comprises an energy storage device coupled with the superconducting magnet and configured to receive and store energy dissipated from the superconducting magnet based on a rapid shutdown condition, and a controller coupled with the energy storage device and programmed to recharge the superconducting magnet using the energy stored in the energy storage device.

In accordance with some embodiments of the present disclosure, an intelligent control system, for dynamically controlling a plurality of components of an MRI system, comprises a processor, configurable by a set of executable instructions storable in relation to a non-transient memory device, to: determine a current-use state of each component of the plurality of components; optimize energy usage among the plurality of components based on the current-use state of each component of the plurality of components, whereby an optimal energy usage is provided; alter an energy consumption profile of each component of the plurality of components based on the optimal energy usage, whereby an altered energy consumption for each component of the plurality of components is provided; automatically activate power to each component of the plurality of components based on the altered energy consumption when the MRI system is to be operated; and automatically deactivate power to each component of the plurality of components based on the altered energy consumption when the MRI system is not to be operated, whereby the MRI system is automatically operable when needed and inoperable when not needed, continually powering the plurality of components is eliminated, and an average energy consumption of the MRI system is reduced over its lifespan.

In accordance with some embodiments of the present disclosure, a method of providing an intelligent control system, for dynamically controlling a plurality of components of an MRI system, comprises providing a processor, configurable by a set of executable instructions storable in relation to a non-transient memory device, to: determine a current-use state of each component of the plurality of components; optimize energy usage among the plurality of components based on the current-use state of each component of the plurality of components, whereby an optimal energy usage is provided; alter an energy consumption profile of each component of the plurality of components based on the optimal energy usage, whereby an altered energy consumption for each component of the plurality of components is provided; automatically activate power to each component of the plurality of components based on the altered energy consumption when the MRI system is to be operated; and automatically deactivate power to each component of the plurality of components based on the altered energy consumption when the MRI system is not to be operated, whereby the MRI system is automatically operable when needed and inoperable when not needed, continually powering the plurality of components is eliminated, and an average energy consumption of the MRI system is reduced over its lifespan.

In accordance with some embodiments of the present disclosure, a method of dynamically controlling a plurality of components of an MRI system, by way of an intelligent control system, comprises providing the intelligent control system, providing the intelligent control system comprising providing a processor, configurable by a set of executable instructions storable in relation to a non-transient memory device, to: determine a current-use state of each component of the plurality of components; optimize energy usage among the plurality of components based on the current-use state of each component of the plurality of components, whereby an optimal energy usage is provided; alter an energy consumption profile of each component of the plurality of components based on the optimal energy usage, whereby an altered energy consumption for each component of the plurality of components is provided; automatically activate power to each component of the plurality of components based on the altered energy consumption when the MRI system is to be operated; and automatically deactivate power to each component of the plurality of components based on the altered energy consumption when the MRI system is not to be operated, whereby the MRI system is automatically operable when needed and inoperable when not needed, continually powering the plurality of components is eliminated, and an average energy consumption of the MRI system is reduced over its lifespan; and operating the intelligent control system.

The details of one or more aspects of the subject matter of the present disclosure are set forth in the accompanying drawings and the below description. Other features, aspects, and advantages of the subject matter will become apparent from the description, the drawings, and the claims.

### BRIEF DESCRIPTION OF THE DRAWINGS

The above, and other, aspects, features, and advantages of several embodiments of the present disclosure will be more apparent from the following Detailed Description as presented in conjunction with the following several figures of the Drawing.

FIG. 1 is a block diagram illustrating an MRI system for rapidly shutting-down and recharging a superconducting magnet, in accordance with an embodiment of the present disclosure.

FIG. 2 is a flow diagram illustrating a method of rapidly shutting-down and recharging a superconducting magnet by way of an MRI system, in accordance with an embodiment of the present disclosure.

FIG. 3 is a block diagram of an MRI system for rapidly shutting-down and recharging a superconducting magnet, in accordance with an embodiment of the present disclosure.

FIG. 4 is a block diagram of an MRI system capable of rapid shutdown and recharge of a superconducting magnet, in accordance with an embodiment of the present disclosure.

FIG. 5 is a bar graph illustrating energy consumption as a function of time period covering exams for three scans corresponding to three patients, in accordance with an embodiment of the present disclosure.

FIG. 6 is a bar graph illustrating energy consumption as a function of time period covering an individual exam for a patient, in accordance with an embodiment of the present disclosure.

FIG. 7 is a block diagram illustrating an intelligent control system for dynamically controlling a plurality of components of an MRI system, as shown in FIGS. 1, 3, and 4, in accordance with an embodiment of the present disclosure.

FIG. 8 is a flow diagram illustrating a method of providing an intelligent control system, as shown in FIG. 7, for dynamically controlling a plurality of components of an MRI system, as shown in FIGS. 1, 3, and 4, in accordance with an embodiment of the present disclosure.

FIG. 9 is a flow diagram illustrating a method of improving energy efficiency in MRI by way of a system, in accordance with an embodiment of the present disclosure.

Corresponding reference numerals or characters indicate corresponding components throughout the several figures of the Drawing(s). Elements in the several figures are illustrated for simplicity and clarity and have not necessarily been drawn to scale. For example, the dimensions of some elements in the several figures may be emphasized relative to other elements for facilitating understanding of the various presently disclosed embodiments. Also, common, but well-understood, elements that are useful or necessary in commercially feasible embodiment are often not depicted to facilitate a less obstructed view of these various embodiments of the present disclosure.

### DETAILED DESCRIPTION

Various embodiments, features, and aspects of the present disclosure are below described with reference to details. The following detailed description and the drawings are illustrative of the present disclosure and are not to be construed as limiting the present disclosure. Numerous specific details are described to provide a thorough understanding of various embodiments of the present disclosure. However, in certain instances, well-known or conventional details are not described in order to provide a concise discussion of embodiments of the present disclosure.

As used herein, the terms “comprises” and “comprising” are to be construed as being inclusive and open ended, and not exclusive. Specifically, when used in the specification and claims, the terms “comprises” and “comprising” as well as variations thereof denote the specified features, steps, or components are included. These terms are not to be interpreted to exclude the presence of other features, steps, or components.

As used herein, the term “exemplary” denotes “serving as an example, instance, or illustration” and should not be construed as preferred or advantageous over other configurations herein disclosed. As used herein, the terms “about” and “approximately” are intended to cover variations that may exist in the upper and lower limits of the ranges of values, such as variations in properties, parameters, and dimensions. In one non-limiting example, the terms “about” and “approximately” denote plus or minus 10 percent or less.

As used herein, the term “determining” encompasses a wide variety of actions; therefore, “determining” includes, but is not limited to, calculating, computing, processing, deriving, investigating, ascertaining, searching, looking-up, e.g., looking-up data or any other information in a table, a database, or another data structure, and the like. Also, “determining” includes, but is not limited to, receiving, e.g., receiving information, accessing, e.g., accessing data in a memory, and the like. Further, “determining” includes, but is not limited to, resolving, selecting, choosing, establishing, and the like. As used herein, the phrase “based on” does not denote “based only on,” unless otherwise expressly specified. In other words, the phrase “based on” denotes both “based only on” as well as “based at least on.”

As described herein, functions of any features of any embodiment of the present disclosure may be stored as one or more instructions on at least one of a processor-readable medium and a computer-readable medium. The term “computer-readable medium” denotes any available medium that is accessible by a computer or processor. By way of example, and not limitation, such a medium may comprise RAM, ROM, EEPROM, flash memory, CD-ROM or other optical disk storage, magnetic disk storage, or other magnetic storage devices, or any other medium, including a cloud server, that is usable for storing desired program code in the form of instructions or data structures and that can be accessed by a computer. A computer-readable medium may be tangible and non-transitory. As used herein, the term “code” may refer to software, instructions, code, or data that is/are executable by a computing device or a processor. A “module” denotes a processor configured to execute computer-readable code.

As described herein, a processor includes, but is not limited to, a general purpose processor, a digital signal processor (DSP), an application specific integrated circuit (ASIC), a field programmable gate array (FPGA) or other programmable logic device, discrete gate or transistor logic, discrete hardware components, or any combination thereof configured to perform the herein described functions. A general purpose processor can be a microprocessor. Alternatively, the processor includes, but is not limited to, a controller, or microcontroller, combinations of the same, or the like. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor includes, but is not limited to, primarily analog components. For example, any of the signal processing algorithms described herein may be implemented in analog circuitry. In some embodiments, a processor includes, but is not limited to, a graphics processing unit (GPU). The parallel processing capabilities of GPUs can reduce the amount of time for training and using neural networks (and other machine learning models) compared to central processing units (CPUs). In some embodiments, a processor includes, but is not limited to, an ASIC including dedicated machine learning circuitry custom-build for one or both of model training and model inference.

As described herein, tasks illustrated in the drawings can be distributed across multiple processors or computing devices of a computer system, including computing devices that are geographically distributed. The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims, and are also encompassed by the present disclosure.

The present disclosure describes systems and methods for rapid magnetic field shutdown and recharging in an MRI system that includes a superconducting magnet cooled by a mechanical cryocooler. Recently, advances in superconductors and superconducting magnet configurations are aimed at reducing the amount of expensive liquid cryogen required to achieve and maintain superconducting properties. These advances include the development of high temperature superconductors that are conductors that become superconducting at temperatures higher than approximately 4 K. Currently, reasonable high temperature superconductors can operate at approximately 10 K; although, some materials can demonstrate superconducting properties at temperatures as high as approximately 30 K. Furthermore, cryogen-free magnet configurations use a cryocooler to cool the magnet coil conductors through thermal contact, rather than by immersing the magnet coils within a liquid helium bath.

The systems and methods described here are based on such a cryogen-free superconducting magnet configuration using traditional, or high temperature, superconductors where the main magnetic field can be turned off in a short amount of time. For instance, the magnetic field can be turned off in an amount of time comparable to a typical amount of time a traditional “quench” would take, e.g., less than 10 seconds.

The MRI system described herein uses a mechanical cryocooler (or cold head) that is in thermal contact with the conductors in a superconducting magnet to cool them to temperatures approaching approximately 4 K. Here, thermal contact comprises direct or indirect contact, through which thermal energy can be transferred or conducted. The superconducting material used for the magnet configuration preferably maintains superconducting properties up to temperatures approaching approximately 8 K. In the herein described system, current density is removed from the conductive windings of the magnet coils in a rapid manner by introducing at least one of a power supply source, a resistive load, and an external energy source.

In one embodiment, a power supply source introduced into the circuit, e.g., via a superconducting switch, is used to supply current to the magnet coils. Supplying current to the magnet coils introduces heat into the system, which can be removed using the thermal cooling capacity of the mechanical cryocooler (or cold head). In another embodiment, a resistive load with a large thermal mass may be introduced into the circuit, e.g., by means of a superconducting switch, and the majority of the energy stored in the superconducting magnet may be dissipated to this load rather than the magnet coils of the superconducting magnet during a rapid shutdown (or ramp down) to turn off the magnetic field. In yet another embodiment, an external energy storage device may be introduced into the circuit, e.g., by means of a superconducting switch, and may be used to store all, or part of the energy contained within the superconducting magnet coils that is dissipated during a rapid shutdown (or ramp down) to turn off the magnetic field. As mentioned, in other embodiments, combinations of the power supply source, resistive load and external energy storage device may be used for rapid shutdown. In addition, one or a combination of the power supply source, the resistive load and the external energy storage device may be used to recharge the magnet coils after a rapid shutdown.

In this system, the rate of energy exchange change (and thus the rate of magnetic field change) can be controlled so that the temperature of the conductor does not exceed a predetermined threshold that could potentially cause irreversible damage. For example, the predetermined threshold may be the superconducting transition point of the magnet coil material. In this manner, there are no rapid resistance changes in the conductor to cause an uncontrolled loss of magnetic field, e.g., a quench. In another example, the predetermined threshold may be a larger temperature than the superconducting transition point, for example, approximately 20 K, so long as the temperature a) doesn't cause significant damage to the wire or magnet structure; and b) doesn't require a significant amount of time to cool back down to superconducting temperature (approximately 4 K to approximately 5K).

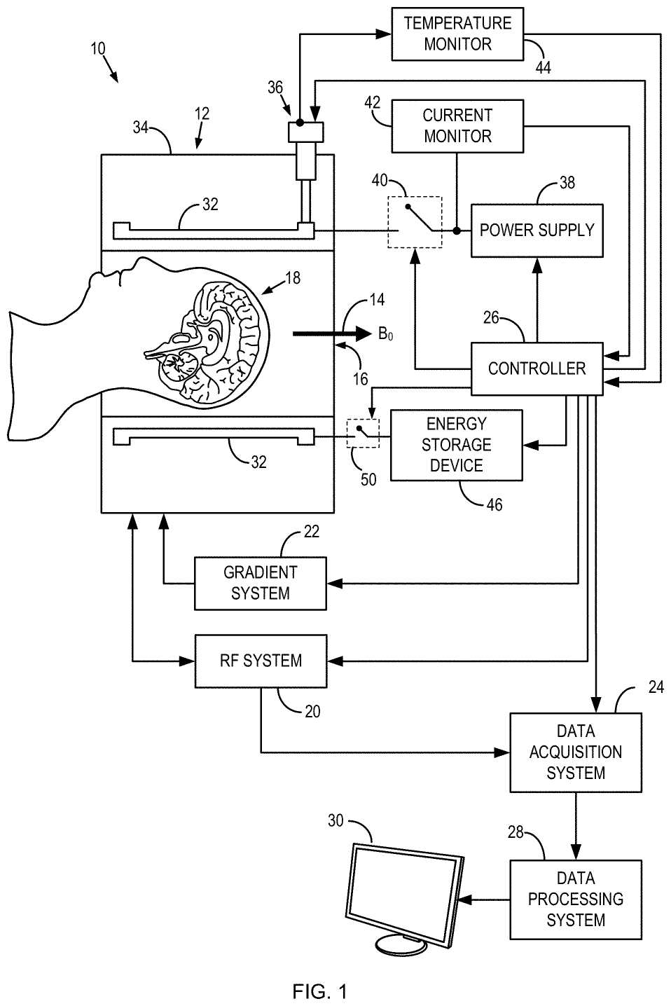

Referring to FIG. 1, this block diagram illustrates an MRI system 10 comprising a magnet assembly 12 for providing a magnetic field 14 that is substantially uniform within a bore 16 configured to accommodate a subject 18 or other object to be imaged, in accordance with an embodiment of the present disclosure. The magnet assembly 12 supports an RF coil (not shown) that may provide an RF excitation to nuclear spins in the object or subject (not shown) positioned within the bore 16. The RF coil communicates with an RF system 20 producing the necessary electrical waveforms. The magnet assembly 12 also supports three axes of gradient coils (not shown), and which communicate with a corresponding gradient system 22 providing electrical power to the gradient coils to produce magnetic field gradients, Gₓ, G_{y}, and G_{z} over time.

Still referring to FIG. 1, a data acquisition system 24 is coupled with RF reception coils (not shown) that are supported within the magnet assembly 12 or positioned within bore 16. Each of the RF system 20, gradient system 22, and data acquisition system 24 communicates with a controller 26 that generates pulse sequences that include RF pulses from the RF system 20 and gradient pulses from the gradient system 22. The data acquisition system 24 receives magnetic resonance signals from the RF system 20 and provides the magnetic resonance signals to a data processing system 28 which operates to process the magnetic resonance signals and reconstruct images therefrom. The reconstructed images can be provided to a display 30 for display to a user.

Still referring to FIG. 1, the magnet assembly 12 includes one or more magnet coils 32 housed in a vacuum housing 34, which generally provides a cryostat for the magnet coils 32, and mechanically cooled by a mechanical cryocooler 36, such as a GIFFORD-MCMAHON® (GM) cryocooler or a pulse tube cryocooler. In one example configuration, the cryocooler comprises a GIFFORD-MCMAHON® Model RDK-305 cryocooler manufactured by Sumitomo Heavy Industries (Japan). In general, the cryocooler 36 is in thermal contact with the magnet coils 32 and is operable to lower the temperature of the magnet coils 32 and to maintain the magnet coils 32 and a desired operating temperature. In some embodiments, the cryocooler 36 includes a first stage in thermal contact with the vacuum housing 34 and a second stage in thermal contact with the magnet coils 32. In these embodiments, the first stage of the cryocooler 36 maintains the vacuum housing 34 at a first temperature and the second stage of the cryocooler 36 maintains the magnet coils 32 at a second temperature that is lower than the first temperature.

Still referring to FIG. 1, the magnet coils 32 comprise a superconducting material and, therefore, provide a superconducting magnet. The superconducting material is preferably selected to be a material with a suitable critical temperature such that the magnet coils 32 are capable of achieving desired magnetic field strengths over a range of suitable temperatures. For example, the superconducting material comprises at least one of: niobium (Nb), having a transition temperature of approximately 9.2 K, niobium-titanium (NbTi), having a transition temperature of approximately 10 K, and triniobium-tin (Nb₃Sn), having a transition temperature of approximately 18.3 K.

Still referring to FIG. 1, the choice of superconducting material defines the range of magnetic field strengths achievable with the magnet assembly 12. Preferably, the superconducting material is chosen such that magnetic field strengths up to approximately 3.0 T are achieved over a range of temperatures that are suitably achieved by the cryocooler 36. In some configurations, however, the superconducting material is chosen to provide magnetic field strengths higher than approximately 3.0 T.

Still referring to FIG. 1, the cryocooler 36 is operable to maintain the magnet coils 32 at an operational temperature at which the magnet coils 32 are superconducting, such as a temperature that is below the transition, or critical, temperature for the material of the magnet coils 32. For example, a lower operational temperature limit is approximately 4 K and an upper operational temperature limit at, or near, the transition, or critical, temperature of the superconducting material of the magnet coils 32.

Still referring to FIG. 1, the current density in the magnet coils 32 in the MRI system 10 is controllable to rapidly ramp up or ramp down the magnetic field 14 generated by the magnet assembly 12 while controlling the temperature of the magnet coils 32 with the cryocooler 36 to keep the temperature below the transition temperature of the superconducting material of the magnet coils 32. For example, the magnetic field 14 is ramped up or ramped down on the order of minutes, such as up to approximately fifteen minutes.

Still referring to FIG. 1, in general, the current density in the magnet coils 32 is increased or decreased by connecting the magnet coils 32 to a circuit with a power supply 38 that is in electrical communication with the magnet coils 32 via a switch 40 and operating the power supply 38 to increase or decrease the current in the connected circuit. The switch 40 is generally a superconducting switch that is operable between a first, closed, state and a second, open, state. When the switch 40 is in its open state, the magnet coils 32 are in a closed circuit, sometimes referred to as a “persistent mode.” In this configuration, the magnet coils 32 are in a superconducting state as long as the temperature of the magnet coils 32 is maintained at a temperature at, or below, the transition temperature of the superconducting material thereof. When the switch 40 is in the closed state, however, the magnet coils 32 and the power supply 38 are placed in a connected circuit; and the current supplied by the power supply 38 and the current in the magnet coils 32 will try to equalize. For instance, if the power supply 38 is operated to supply more current to the connected circuit, the current in the magnet coils 32 will increase, thereby increasing the strength of the magnetic field 14. On the other hand, if the power supply 38 is operated to decrease the current in the connected circuit, the current in the magnet coils 32 decreases, thereby decreasing the strength of the magnetic field 14.

Still referring to FIG. 1, any suitable superconducting switch can be used for selectively connecting the magnet coils 32 and power supply 38 into a connected circuit; however, as one non-limiting example, the switch 40 comprises a length of superconducting wire that is connected in parallel to the magnet coils 32 and the power supply 38. To operate such a switch 40 into its closed state, a heater in thermal contact with the switch 40 is operated to raise the temperature of the superconducting wire above its transition temperature, which, in turn, renders the wire highly resistive relative to the inductive impedance of the magnet coils 32. As a result, very little current will flow through the switch 40. The power supply 38 is then disposed in a connected circuit with the magnet coils 32. When in this connected circuit, the current in the power supply 38, and the magnet coils 32 will try to equalize. Thus, by adjusting the current supplied by the power supply 38, the current density in the magnet coils 32 is increased or decreased to respectively ramp up or ramp down the magnetic field 14. To operate the switch 40 into its open state, the superconducting wire in the switch 40 is cooled below its transition temperature, which places the magnet coils 32 back into a closed circuit, thereby disconnecting the power supply 38 and allowing all of the current to flow through the magnet coils 32.

Still referring to FIG. 1, when the magnet coils 32 are in the connected circuit with the power supply 38, the temperature of the magnet coils 32 increases as the current in the connected circuit equalizes. Thus, the temperature of the magnet coils 32 should be monitored to ensure that the temperature of the magnet coils 32 remains below the transition temperature for the superconducting material thereof. Because placing the magnet coils 32 into a connected circuit with the power supply 38 will tend to increase the temperature of the magnet coils 32, the rate at which the magnetic field 14 is ramped up or ramped down depends, in part, on the cooling capacity of the cryocooler 36. For instance, a cryocooler with a larger cooling capacity is able to more rapidly remove heat from the magnet coils 32 while they are in a connected circuit with the power supply 38.

Still referring to FIG. 1, the power supply 38 and the switch 40 are operable by the controller 26 to provide current to the magnet coils 32 when the power supply 38 is in a connected circuit with the magnet coils 32. A current monitor 42 measures the current flowing to the magnet coils 32 from the power supply 38; and a measure of the current is provided to the controller 26 for controlling the ramping up or ramping down of the magnetic field 14. In some configurations, the current monitor 42 is integrated with the power supply 38.

Still referring to FIG. 1, a temperature monitor 44 is in thermal contact with the magnet assembly 12 and operates to measure a temperature of the magnet coils 32 in real-time. For example, the temperature monitor 44 comprises a thermocouple temperature sensor, a diode temperature sensor, e.g., a silicon diode or a gallium aluminum aresenide (GaAlAs) diode, a resistance temperature detector (RTD), a capacitive temperature sensor, and the like. RTD-based temperature sensors comprise at least one of a ceramic oxynitride material, a germanium material, and a ruthenium oxide material. The temperature of the magnet coils 32 is monitored and provided to the controller 26 for controlling the ramping up or ramping down of the magnetic field 14.

Still referring to FIG. 1, in operation, the controller 26 is programmed to ramp up or ramp down the magnetic field 14 of the magnet assembly 12 in response to instructions from a user. The magnetic field 14 is ramped down by decreasing the current density in the magnet coils 32 by supplying current to the magnet coils 32 from the power supply 38 via the switch 40, which is controlled by the controller 26. Likewise, the strength of the magnetic field 14 is ramped up by increasing the current density in the magnet coils 32 by supplying current to the magnet coils 32 from the power supply 38 via the switch 40, which is controlled by the controller 26.

Still referring to FIG. 1, the controller 26 is also programmed to monitor various operational parameter values associated with the MRI system 10 before, during, and after ramping up or down the magnetic field 14. For example, the controller 26 monitors the current supplied to the magnet coils 32 by the power supply 38 via data received from the current monitor 42. As another example, the controller 26 monitors the temperature of the magnet coils 32 via data received from the temperature monitor 44. As still another example, the controller 26 monitors the strength of the magnetic field 14, such as by receiving data from a magnetic field sensor, e.g., via a Hall probe or the like, positioned in, or proximate to, the bore 16 of the magnet assembly 12.

Still referring to FIG. 1, certain conditions or situations may require that the magnetic field 14 of the magnet assembly 12 be shut down (or turned off) rapidly. For example, an emergency situation may be created by a large metallic object being attracted by the strong magnetic field of the magnet assembly 12. In one embodiment, the power supply source 38 is also used to rapidly shutdown the magnetic field 14 of the magnet assembly 12 in response to a shutdown condition. The power supply source 38 is connected to the magnet coils 32 and operated to remove or decrease the current in the magnet coils 32. The cryocooler 36 is used to remove heat generated by the magnet coils 32 as the current in the magnet coils 32 decreases. In an embodiment, the temperature monitor 44 is used to measure a temperature of the magnet coils 32 in real-time. The controller 26 is configured to rapidly shutdown (or turn off) the magnet field 14 of the magnet assembly 12 in response to instructions from a user. The user provides instructions to the controller based on the presence of a shutdown condition.

Still referring to FIG. 1, in another embodiment, a rapid shutdown, e.g., an emergency shutdown, of the magnet field of the magnet assembly 12 is performed by using an energy storage device 46 coupled with the magnet coils 32 and the controller 26. In one embodiment, the energy storage device comprises an inductive load. For example, the inductive load comprises a second superconducting system. The second superconducting system is thermally coupled with the cryocooler 36 of MRI system 10 and cooled by the cryocooler 36. In another embodiment, the energy storage device 46 comprises a battery. The energy storage device 46 is coupled with the magnet coils 32 using a superconducting switch 50. The superconducting switch 50 is controlled by using, for example, the controller 26 to selectively connect the energy storage device 46 and the magnet coils 32 into a connected circuit. In an embodiment, the superconducting switch 50 comprises any suitable superconducting switch usable for selectively connecting the magnet coils 32 and energy storage device 46 into a connected circuit. For example, the superconducting switch 50 is switched between an open state and a closed state as herein described.

Still referring to FIG. 1, the energy storage device 46 may be used to store all, or a part of, the energy contained in the magnet coils 32 so that the current density is removed from the magnet coils 32 and the magnetic field 14 turned off. In other words, the energy from the magnet coils 32 may be dissipated into the energy storage device 46 during the rapid shutdown of the magnetic field 46. In an embodiment, the magnetic field 14 may be turned off in a short amount of time, for example, in an amount of time comparable to a typicality amount of time a transitional “quench” would take, e.g., less than 10 seconds). The controller 26 may be configured to rapidly shutdown (or turn off) the magnet field 14 of the magnet assembly 12 in response to instructions from a user. The user may provide instructions to the controller 26 based on the presence of a shutdown condition.

Still referring to FIG. 1, the rate of energy exchange change, and, thus, the rate of magnetic field change, is controlled so that the temperature of the conductor (magnet coils 32) does not exceed a predetermined threshold that could potentially cause irreversible damage. For example, the predetermined threshold comprises the superconducting transition point of the magnet coil 32 material. In another example, the predetermined threshold comprises a larger temperature than the superconducting transition point, for example, 20K. In an embodiment, the temperature monitor 44 is used to measure a temperature of the magnet coils 32 in real-time. The temperature of the magnet coils 32 is monitored; and the temperature is provided to the controller 26 to control the raid shutdown of the magnetic field 14.

Still referring to FIG. 1, after the magnetic field 14 has been shut down (or turned off), the condition(s) that led to the need for the rapid shutdown may be resolved. Once the rapid shutdown condition is resolved, the energy stored in the energy storage device 46, from the shutdown of the magnetic field 14, is used to fully, or partially, recharge the magnet coils 32. The controller 26 is configured to recharge the magnet coils 32 using the energy stored in the energy storage device 46 from the shutdown of the magnetic field 14 in response to instructions from a user. For example, the energy storage device 46 and the superconducting switch 50 operate under control from the controller 26 to provide the energy stored in the energy storage device 46 to the magnet coils 32 when the energy storage device 46 is in a connected circuit with the magnet coils 32.

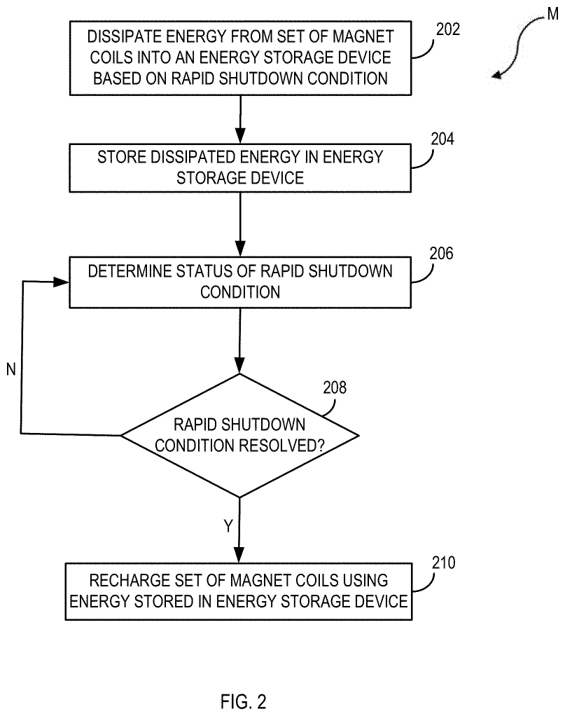

Referring to FIG. 2, this flow diagram illustrates a method M for rapid shutdown and recharge of a superconducting magnet, in accordance with an embodiment of the present disclosure. At block 202, energy from a set of magnet coils in a magnet assembly of an MRI system 10 is dissipated to an energy storage device coupled with the magnet coils. The energy is dissipated based on a rapid shutdown condition, for example, the presence of a large metallic object that is attracted by the strong magnetic field of the MRI system 10. In an embodiment, a user provides instructions to the MRI system 10 to rapidly shutdown the magnetic field of the magnet assembly. For example, a superconducting switch is used to connect the energy storage device to the magnet coils. During the shutdown of the magnetic field, current density is removed from the magnet coils and the energy is dissipated to the energy storage device. In an embodiment, the magnetic field is turned off in a short amount of time, for example, in an amount of time comparable to a typicality amount of time a transitional “quench” would take, e.g., less than approximately 10 seconds. The rate of energy exchange change (and thus the rate of magnetic field change) is controlled so that the temperature of the conductor does not exceed a predetermined threshold that could potentially cause irreversible damage. In an embodiment, a temperature monitor is used to measure a temperature of the magnet coils in real-time. The temperature of the magnet coils is monitored and the temperature may be provided to a controller of the MRI system to control the raid shutdown of the magnetic field 14.

Still referring to FIG. 2, at block 204, the energy dissipated from the magnet coils is stored in the energy storage device. The energy storage device comprises, for example, an inductive load or a battery. After the magnetic field is turned off, the status of the rapid shutdown condition is determined at block 206. If the rapid shutdown condition is not resolved at block 208, the magnetic field remains turned off until the issue is resolved. If the rapid shutdown condition is resolved at block 208, the magnet coils of the magnet assembly are recharged by using the energy stored in the energy storage device at block 210. In an embodiment, a user provides instructions to the MRI system 10 to recharge of the magnet coils of the magnet assembly.

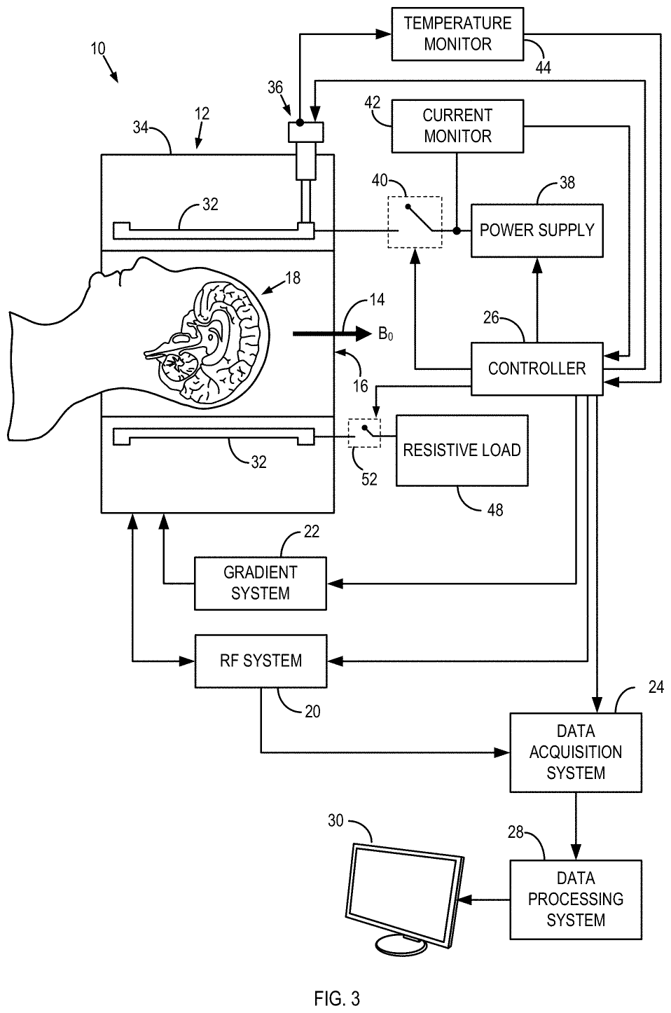

Referring to FIG. 3, this block diagram illustrates an MRI system 10 capable of rapid shutdown of a superconducting magnet, in accordance with an embodiment of the present disclosure. The rapid shutdown, e.g., an emergency shutdown, of the magnet coils 32 is performed by using a resistive load coupled with the magnet coils 32. The elements and operation of MRI system 10 are similar to the MRI system, as shown in FIG. 1. The MRI system 10 comprises a resistive load 48 coupled with magnet coils 32 of a magnet assembly 12. In an embodiment, the resistive load 48 has a large thermal mass. The resistive load 48 is coupled with the magnet coils 32 by using a superconducting switch 52. The superconducting switch 52 is controlled by using, for example, the controller 26 to selectively connect the resistive load 48 and the magnet coils 32 into a connected circuit.

Still referring to FIG. 3, in an embodiment, the superconducting switch 52 comprises any suitable superconducting switch usable for selectively connecting the magnet coils 32 and resistive load 48 into a connected circuit. For example, the superconducting switch 52 is switched between an open state and a closed state as herein described. Energy from the magnet coils 32 is dissipated to the resistive load 48 during rapid shutdown of the magnetic field 14. In an embodiment, the magnetic field 14 is turned off in a short amount of time, for example, in an amount of time comparable to a typical amount of time that a transitional “quench” would take, e.g., less than approximately 10 seconds. The rate of energy exchange change (and thus the rate of magnetic field change) is controlled so that the temperature of the conductor (magnet coils 32) does not exceed a predetermined threshold that could potentially cause irreversible damage. In an embodiment, a temperature monitor 44 is used to measure a temperature of the magnet coils 32 in real-time. The temperature of the magnet coils 32 is monitored; and the temperature is provided to a controller 26 for controlling the rapid shutdown of the magnetic field 14. The controller 26 is configured to rapidly shutdown (or turn off) the magnet field 14 of the magnet assembly 12 in response to instructions from a user. The user provides instructions to the controller based on the presence of a shutdown condition.

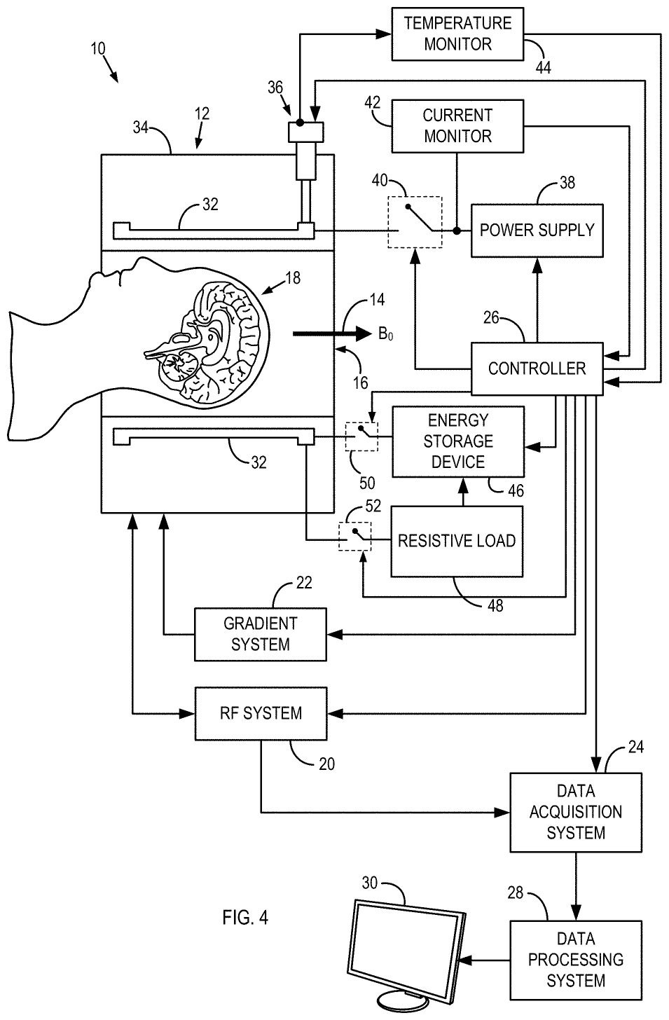

Referring to FIG. 4, this block diagram illustrates an MRI system 10 capable of rapid shutdown of a superconducting magnet, in accordance with an embodiment of the present disclosure. A resistive load is used in combination with an energy storage device to rapidly shutdown and recharge the magnet coils. The elements and operation of MRI system 10 are similar to the MRI system 10, as shown in FIG. 1. The MRI system 10 comprises a resistive load 48 coupled with magnet coils 32 of a magnet assembly 12 and with an energy storage device 46. The energy storage device 46 is coupled with a controller 26. In one embodiment, the energy storage device comprises an inductive load. For example, the inductive load comprises a second superconducting system. The second superconducting system is thermally coupled with the cryocooler 36 of MRI system 10 and cooled by the cryocooler 36.

Still referring to FIG. 4, in another embodiment, the energy storage device 46 comprises a battery. The energy storage device 46 is coupled with the magnet coils 32 by using a superconducting switch 50; and the resistive load 48 is coupled with the magnet coils 32 by using a superconducting switch 52. The superconducting switches 50, 52 are controlled by using, for example, the controller 26 to selectively connect the energy storage device 46 and the resistive load 48, respectively, and the magnet coils 32 into a connected circuit. In an embodiment, the superconducting switches 50, 52 comprise any suitable superconducting switch that is usable for selectively connecting the magnet coils 32 and resistive load 48 into a connected circuit. For example, the superconducting switches 50, 52 are switched between an open state and a closed state as herein described.

Still referring to FIG. 4, energy from the magnet coils 32 is dissipated to the resistive load 48 during rapid shutdown of the magnetic field 14. The controller 26 is configured to rapidly shutdown (or turn off) the magnet field 14 of the magnet assembly 12 in response to instructions from a user. The user provides instructions to the controller 26 based on the presence of a shutdown condition. Thermal energy (or heat) dissipated by the resistive load 48 is used to charge the energy storage device 46. The rate of energy exchange change (and thus the rate of magnetic field change) is controlled so that the temperature of the conductor (magnet coils 32) does not exceed a predetermined threshold that could potentially cause irreversible damage. In an embodiment, a temperature monitor 44 is used to measure a temperature of the magnet coils 32 in real-time. The temperature of the magnet coils 32 is monitored; and the temperature is provided to a controller 26 for controlling the rapid shutdown of the magnetic field 14.

Still referring to FIG. 4, after the magnetic field 14 is shut down (or turned off), the condition(s) that led to the need for the rapid shutdown may be resolved. Once the rapid shutdown condition is resolved, the energy stored in the energy storage device 46 from the resistive load 48 is used to fully, or partially, recharge the magnet coils 32. The controller 26 is configured to recharge the magnet coils 32 by using the energy stored in the energy storage device 46 in response to instructions from a user. For example, the energy storage device 46 and the superconducting switch 50 are operable by the controller 26 to provide the energy stored in the energy storage device 46 to the magnet coils 32 when the energy storage device 46 is in a connected circuit with the magnet coils 32.

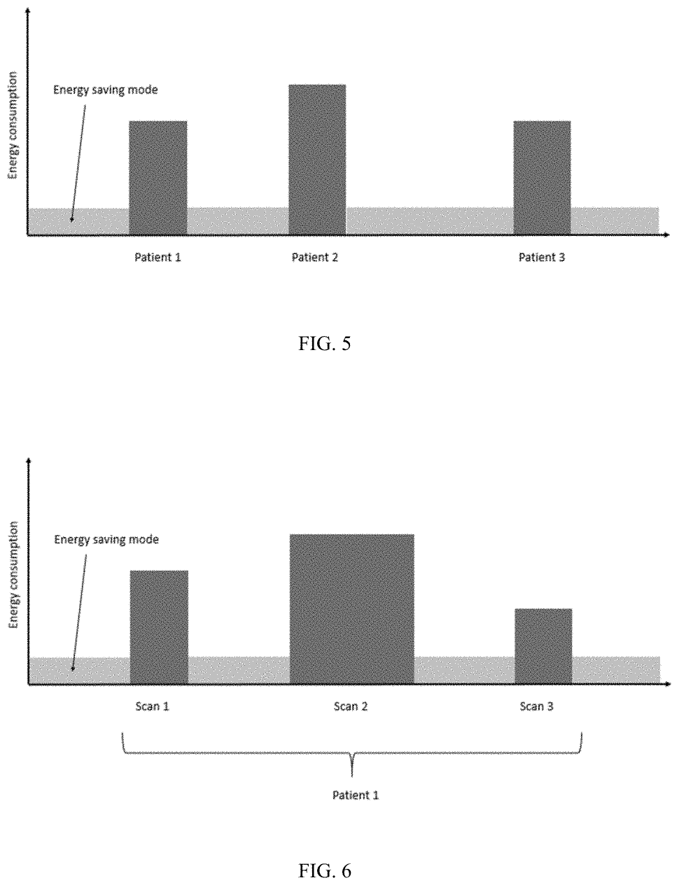

Referring to FIG. 5, this bar graph illustrates energy consumption as a function of time period covering exams for three scans corresponding to three patients, in accordance with an embodiment of the present disclosure. In the time between each scan of each patient, the MRI system 10 is placed into a low power consumption mode.

Referring to FIG. 6, this bar graph illustrates energy consumption as a function of time period covering an individual exam for a patient, in accordance with an embodiment of the present disclosure. The exam is composed of multiple scans. In between the scans of the same patient, the MRI system 10 is placed into a low power consumption mode.

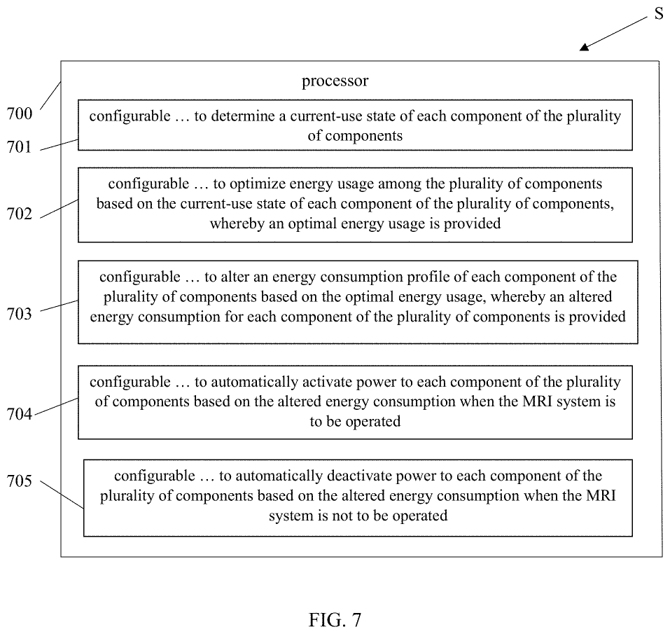

Referring to FIG. 7, this block diagram illustrates an intelligent control system S, for dynamically controlling a plurality of components of an MRI system, e.g., an MRI system 10, as shown in FIGS. 1, 3, and 4, in accordance with an embodiment of the present disclosure. The intelligent control system S comprises a processor 700, configurable by a set of executable instructions storable in relation to a non-transient memory device (not shown), to: determine a current-use state of each component of the plurality of components, as indicated by block 701; optimize energy usage among the plurality of components based on the current-use state of each component of the plurality of components, whereby an optimal energy usage is provided, as indicated by block 702; alter an energy consumption profile of each component of the plurality of components based on the optimal energy usage, whereby an altered energy consumption for each component of the plurality of components is provided, as indicated by block 703; automatically activate power to each component of the plurality of components based on the altered energy consumption when the MRI system, e.g., an MRI system 10, is to be operated, as indicated by block 704; and automatically deactivate power to each component of the plurality of components based on the altered energy consumption when the MRI system, e.g., an MRI system 10, is not to be operated, as indicated by block 705, whereby the MRI system, e.g., an MRI system 10, is automatically operable when needed and inoperable when not needed, continually powering the plurality of components is eliminated, and an average energy consumption of the MRI system is reduced over its lifespan.

Still referring to FIG. 7, in the intelligent control system S, the plurality of components comprises at least one of a superconducting electromagnet and an MRI scanner. The plurality of components further comprises at least one of at least one amplifier, e.g., a gradient amplifier and a radio-frequency (RF) amplifier, a cooling system, and a high-performance computer. The processor 700 is further configured by the set of executable instructions storable in relation to the non-transient memory device (not shown), to dynamically control the at least one component of the plurality of components by at least one of: disabling the at least one amplifier, deactivating the at least one amplifier, switching between different types of amplifiers, switching between different types of power sources, using a low-power source for a low-power scan while a high-power source is warming to avoid delay, changing a power consumption mode of the cooling system, changing frequency of a cooling loop, disabling one cryogenic cooler of a plurality of cryogenic coolers, cycling a plurality of cooling systems between activation and deactivation, and placing at last one computer system in at least one of a standby mode and a low-power mode, wherein a low-energy protocol triggers using a low-energy amplifier, and wherein a high-performance imaging requirement triggers using a combination of a high-power amplifier and a high-power source.

Still referring to FIG. 7, in the intelligent control system S, the processor 700 is further configured by the set of executable instructions storable in relation to the non-transient memory device (not shown), to dynamically control the at least one component of the plurality of components during at least one of: within a scan, in between scans of a plurality of scans within an examination, in between accommodating patients of a plurality of patients, overnight, and when the MRI system 10 is ramped-down.

Still referring to FIG. 7, in the intelligent control system S, the processor 700 is further configured by the set of executable instructions storable in relation to the non-transient memory device (not shown), to dynamically control the at least one component of the plurality of components by automatically adjusting the at least one component of the plurality of components based on scanner state. Optionally, in the intelligent control system S, the processor 700 is further configured by the set of executable instructions storable in relation to the non-transient memory device (not shown), to dynamically control a plurality of subcomponents for optimal energy usage concerns.

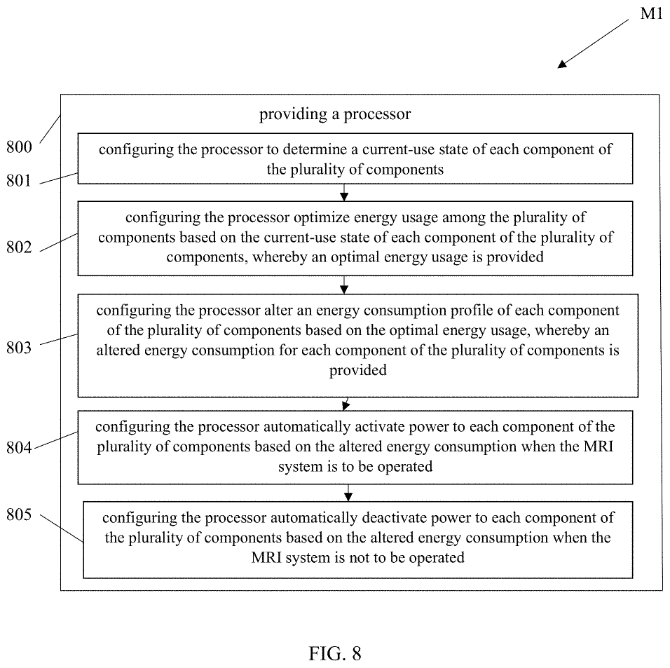

Referring to FIG. 8, this flow diagram illustrates a method M1 of providing an intelligent control system S, e.g., as shown in FIG. 7, for dynamically controlling a plurality of components of an MRI system, e.g., an MRI system 10, as shown in FIGS. 1, 3, and 4, in accordance with an embodiment of the present disclosure. The method M1 comprises providing a processor 700, configurable by a set of executable instructions storable in relation to a non-transient memory device, as indicated by block 800, to: determine a current-use state of each component of the plurality of components, as indicated by block 801; optimize energy usage among the plurality of components based on the current-use state of each component of the plurality of components, whereby an optimal energy usage is provided, as indicated by block 802; alter an energy consumption profile of each component of the plurality of components based on the optimal energy usage, whereby an altered energy consumption for each component of the plurality of components is provided, as indicated by block 803; automatically activate power to each component of the plurality of components based on the altered energy consumption when the MRI system, e.g., an MRI system 10, is to be operated, as indicated by block 804; and automatically deactivate power to each component of the plurality of components based on the altered energy consumption when the MRI system, e.g., an MRI system 10, is not to be operated, as indicated by block 805, whereby the MRI system, e.g., an MRI system 10, is automatically operable when needed and inoperable when not needed, continually powering the plurality of components is eliminated, and an average energy consumption of the MRI system, e.g., an MRI system 10, is reduced over its lifespan.

Still referring to FIG. 8, in the method M1, providing the processor 700, as indicated by block 800, comprises configuring the processor 700 to determine the current-use state of each component of the plurality of components comprising at least one of a superconducting electromagnet and an MRI scanner. Providing the processor 700 comprises configuring the processor 700 to determine the current-use state of each component of the plurality of components further comprising at least one of at least one amplifier, at least one cooling system, and at least one computer. Providing the processor 700 comprises configuring the processor 700 to determine the current-use state of each component of the plurality of components further comprising the at least one amplifier comprising at least one of a gradient amplifier and a radio-frequency (RF) amplifier.

Still referring to FIG. 8, in the method M1, providing the processor 700 comprises configuring the processor 700 to at least one of: disable the at least one amplifier, deactivate the at least one amplifier, switch between different types of amplifiers, switch between different types of power sources, use a low-power source for a low-power scan while a high-power source is warming to avoid delay, change a power consumption mode of the at least one cooling system, change frequency of at least one cooling loop of the at least one cooling system, disable at least one cryogenic cooler of a plurality of cryogenic coolers, cycle the at least one cooling system between activation and deactivation, and place the at last one computer in at least one of a standby mode and a low-power mode, wherein a low-energy protocol triggers using a low-energy amplifier, and wherein a high-performance imaging requirement triggers using a combination of a high-power amplifier and a high-power source.

Still referring to FIG. 8, in the method M1, providing the processor 700 comprises further configuring the processor 700 to at least one of: dynamically control the at least one component of the plurality of components during at least one of: within a scan, in between scans of a plurality of scans within an examination, in between accommodating patients of a plurality of patients, overnight, and when the MRI system is ramped-down; dynamically control the at least one component of the plurality of components by automatically adjusting the at least one component of the plurality of components based on scanner state; and dynamically control a plurality of subcomponents based optimal energy usage.

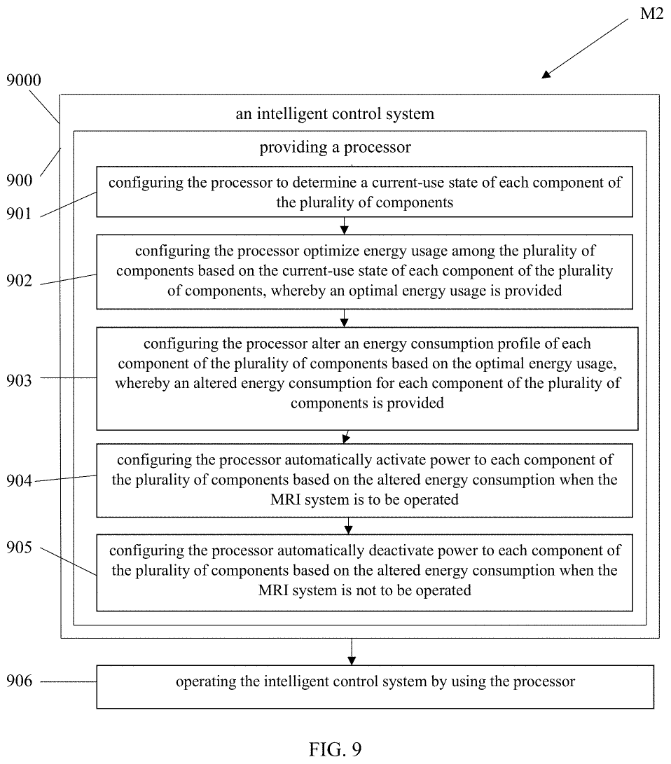

FIG. 9 is a flow diagram illustrating illustrates a method M2 of dynamically controlling a plurality of components of an MRI system, e.g., an MRI system 10, as shown in FIGS. 1, 3, and 4, by way of an intelligent control system S, e.g., as shown in FIG. 7, in accordance with an embodiment of the present disclosure. The method M2 comprises providing the intelligent control system S, as indicated by block 9000, providing the intelligent control system S comprising providing a processor 700, as indicated by block 900, configurable by a set of executable instructions storable in relation to a non-transient memory device, to: determine a current-use state of each component of the plurality of components, as indicated by block 901; optimize energy usage among the plurality of components based on the current-use state of each component of the plurality of components, whereby an optimal energy usage is provided, as indicated by block 902; alter an energy consumption profile of each component of the plurality of components based on the optimal energy usage, whereby an altered energy consumption for each component of the plurality of components is provided, as indicated by block 903; automatically activate power to each component of the plurality of components based on the altered energy consumption when the MRI system, e.g., an MRI system 10, is to be operated, as indicated by block 904; and automatically deactivate power to each component of the plurality of components based on the altered energy consumption when the MRI system, e.g., an MRI system 10, is not to be operated, as indicated by block 905, whereby the MRI system, e.g., an MRI system 10, is automatically operable when needed and inoperable when not needed, continually powering the plurality of components is eliminated, and an average energy consumption of the MRI system, e.g., an MRI system 10, is reduced over its lifespan; and operating the intelligent control system by using the processor, as indicated by block 906.

Still referring to FIG. 9, in the method M2, providing the processor 700, as indicated by block 800, comprises configuring the processor 700 to determine the current-use state of each component of the plurality of components comprising at least one of a superconducting electromagnet and an MRI scanner. Providing the processor 700 comprises configuring the processor 700 to determine the current-use state of each component of the plurality of components further comprising at least one of at least one amplifier, at least one cooling system, and at least one computer. Providing the processor 700 comprises configuring the processor 700 to determine the current-use state of each component of the plurality of components further comprising the at least one amplifier comprising at least one of a gradient amplifier and a radio-frequency (RF) amplifier.

Still referring to FIG. 9, in the method M2, providing the processor 700 comprises configuring the processor 700 to at least one of: disable the at least one amplifier, deactivate the at least one amplifier, switch between different types of amplifiers, switch between different types of power sources, use a low-power source for a low-power scan while a high-power source is warming to avoid delay, change a power consumption mode of the at least one cooling system, change frequency of at least one cooling loop of the at least one cooling system, disable at least one cryogenic cooler of a plurality of cryogenic coolers, cycle the at least one cooling system between activation and deactivation, and place the at last one computer in at least one of a standby mode and a low-power mode, wherein a low-energy protocol triggers using a low-energy amplifier, and wherein a high-performance imaging requirement triggers using a combination of a high-power amplifier and a high-power source.

Still referring to FIG. 9, in the method M2, providing the processor 700 comprises further configuring the processor 700 to at least one of: dynamically control the at least one component of the plurality of components during at least one of: within a scan, in between scans of a plurality of scans within an examination, in between accommodating patients of a plurality of patients, overnight, and when the MRI system is ramped-down; dynamically control the at least one component of the plurality of components by automatically adjusting the at least one component of the plurality of components based on scanner state; and dynamically control a plurality of subcomponents based optimal energy usage.

The functions described herein may be stored as one or more instructions on a processor-readable or computer-readable medium. The term “computer-readable medium” refers to any available medium that can be accessed by a computer or processor. By way of example, and not limitation, such a medium may comprise RAM, ROM, EEPROM, flash memory, CD-ROM or other optical disk storage, magnetic disk storage or other magnetic storage devices, or any other medium that can be used to store desired program code in the form of instructions or data structures and that can be accessed by a computer. It should be noted that a computer-readable medium may be tangible and non-transitory. As used herein, the term “code” may refer to software, instructions, code or data that is/are executable by a computing device or processor. A “module” can be considered as a processor executing computer-readable code.

A processor as described herein can be a general purpose processor, a digital signal processor (DSP), an application specific integrated circuit (ASIC), a field programmable gate array (FPGA) or other programmable logic device, discrete gate or transistor logic, discrete hardware components, or any combination thereof configured to perform the functions described herein. A general purpose processor can be a microprocessor, but in the alternative, the processor can be a controller, or microcontroller, combinations of the same, or the like. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor may also include primarily analog components. For example, any of the signal processing algorithms described herein may be implemented in analog circuitry. In some embodiments, a processor can be a graphics processing unit (GPU). The parallel processing capabilities of GPUs can reduce the amount of time for training and using neural networks (and other machine learning models) compared to central processing units (CPUs). In some embodiments, a processor can be an ASIC including dedicated machine learning circuitry custom-build for one or both of model training and model inference. The disclosed or illustrated tasks can be distributed across multiple processors or computing devices of a computer system, including computing devices that are geographically distributed.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

The specific embodiments described above have been shown by way of example, and understood is that these embodiments may be susceptible to various modifications and alternative forms. Further understood is that the claims are not intended to be limited to the particular forms disclosed, but rather to cover all modifications, equivalents, and alternatives falling within the spirit and scope of this disclosure. While the foregoing written description of the system enables one of ordinary skill to make and use what is considered presently to be the best mode thereof, those of ordinary skill will understand and appreciate the existence of variations, combinations, and equivalents of the specific embodiment, method, and examples herein. The system should therefore not be limited by the above described embodiment, method, and examples, but by all embodiments and methods within the scope and spirit of the system. Thus, the present disclosure is not intended to be limited to the implementations shown herein but is to be accorded the widest scope consistent with the principles and novel features disclosed herein.

Information as herein shown and described in detail is fully capable of attaining the above-described object of the present disclosure, the presently preferred embodiment of the present disclosure, and is, thus, representative of the subject matter which is broadly contemplated by the present disclosure. The scope of the present disclosure fully encompasses other embodiments which may become obvious to those skilled in the art, and is to be limited, accordingly, by nothing other than the appended claims, wherein any reference to an element being made in the singular is not intended to mean “one and only one” unless explicitly so stated, but rather “one or more.” All structural and functional equivalents to the elements of the above-described preferred embodiment and additional embodiments as regarded by those of ordinary skill in the art are hereby expressly incorporated by reference and are intended to be encompassed by the present claims.

Moreover, no requirement exists for a system or method to address each and every problem sought to be resolved by the present disclosure, for such to be encompassed by the present claims. Furthermore, no element, component, or method step in the present disclosure is intended to be dedicated to the public regardless of whether the element, component, or method step is explicitly recited in the claims. However, various changes and modifications in form, material, work-piece, and fabrication material detail may be made, without departing from the spirit and scope of the present disclosure, as set forth in the appended claims, as may be apparent to those of ordinary skill in the art, are also encompassed by the present disclosure.

### INDUSTRIAL APPLICABILITY

Generally, the present disclosure industrially applies to MRI. More specifically, the present disclosure industrially applies to power consumption in MRI. Even more specifically, the present disclosure industrially applies to a system for improving power consumption in MRI.

What is claimed:

1. An intelligent control system for dynamically controlling a plurality of components of an MRI system, the intelligent control system comprising a processor, configurable by a set of executable instructions storable in relation to a non-transient memory device, to:
determine a current-use state of each component of the plurality of components;
optimize energy usage among the plurality of components based on the current-use state of each component of the plurality of components, whereby an optimal energy usage is provided;
alter an energy consumption profile of each component of the plurality of components based on the optimal energy usage, whereby an altered energy consumption for each component of the plurality of components is provided;
automatically activate power to each component of the plurality of components based on the altered energy consumption when the MRI system is to be operated; and
automatically deactivate power to each component of the plurality of components based on the altered energy consumption when the MRI system is not to be operated,
whereby the MRI system is automatically operable when needed and inoperable when not needed, continually powering the plurality of components is eliminated, and an average energy consumption of the MRI system is reduced over its lifespan.

2. The intelligent control system of claim 1, wherein the plurality of components comprises at least one of a superconducting electromagnet and an MRI scanner.

3. The intelligent control system of claim 2, wherein the plurality of components further comprises at least one of at least one amplifier, at least one cooling system, and at least one computer.

4. The intelligent control system of claim 3, wherein the at least one amplifier comprises at least one of a gradient amplifier and a radio-frequency (RF) amplifier.

5. The intelligent control system of claim 3,
wherein the processor is further configured to at least one of: disable the at least one amplifier, deactivate the at least one amplifier, switch between different types of amplifiers, switch between different types of power sources, use a low-power source for a low-power scan while a high-power source is warming to avoid delay, change a power consumption mode of the at least one cooling system, change frequency of at least one cooling loop of the at least one cooling system, disable at least one cryogenic cooler of a plurality of cryogenic coolers, cycle the at least one cooling system between activation and deactivation, and place the at last one computer in at least one of a standby mode and a low-power mode,
wherein a low-energy protocol triggers using a low-energy amplifier, and
wherein a high-performance imaging requirement triggers using a combination of a high-power amplifier and a high-power source.

6. The intelligent control system of claim 5, wherein the processor is further configured to at least one of:
dynamically control the at least one component of the plurality of components during at least one of: within a scan, in between scans of a plurality of scans within an examination, in between accommodating patients of a plurality of patients, overnight, and when the MRI system is ramped-down; and
dynamically control the at least one component of the plurality of components by automatically adjusting the at least one component of the plurality of components based on scanner state.

7. The intelligent control system of claim 1, wherein the processor is further configured to dynamically control a plurality of subcomponents based optimal energy usage.

8. A method of providing an intelligent control system for dynamically controlling a plurality of components of an MRI system, the method comprising providing a processor, configurable by a set of executable instructions storable in relation to a non-transient memory device, to:
determine a current-use state of each component of the plurality of components;
optimize energy usage among the plurality of components based on the current-use state of each component of the plurality of components, whereby an optimal energy usage is provided;
alter an energy consumption profile of each component of the plurality of components based on the optimal energy usage, whereby an altered energy consumption for each component of the plurality of components is provided;
automatically activate power to each component of the plurality of components based on the altered energy consumption when the MRI system is to be operated; and
automatically deactivate power to each component of the plurality of components based on the altered energy consumption when the MRI system is not to be operated,
whereby the MRI system is automatically operable when needed and inoperable when not needed, continually powering the plurality of components is eliminated, and an average energy consumption of the MRI system is reduced over its lifespan.

9. The method of claim 8, wherein providing the processor comprises configuring the processor to determine the current-use state of each component of the plurality of components comprising at least one of a superconducting electromagnet and an MRI scanner.

10. The method of claim 9, wherein providing the processor comprises configuring the processor to determine the current-use state of each component of the plurality of components further comprising at least one of at least one amplifier, at least one cooling system, and at least one computer.

11. The method of claim 10, wherein providing the processor comprises configuring the processor to determine the current-use state of each component of the plurality of components further comprising the at least one amplifier comprising at least one of a gradient amplifier and a radio-frequency (RF) amplifier.

12. The method of claim 10,
wherein providing the processor comprises configuring the processor to at least one of: disable the at least one amplifier, deactivate the at least one amplifier, switch between different types of amplifiers, switch between different types of power sources, use a low-power source for a low-power scan while a high-power source is warming to avoid delay, change a power consumption mode of the at least one cooling system, change frequency of at least one cooling loop of the at least one cooling system, disable at least one cryogenic cooler of a plurality of cryogenic coolers, cycle the at least one cooling system between activation and deactivation, and place the at last one computer in at least one of a standby mode and a low-power mode,
wherein a low-energy protocol triggers using a low-energy amplifier, and
wherein a high-performance imaging requirement triggers using a combination of a high-power amplifier and a high-power source.

13. The method of claim 12, wherein providing the processor comprises further configuring the processor to at least one of:
dynamically control the at least one component of the plurality of components during at least one of: within a scan, in between scans of a plurality of scans within an examination, in between accommodating patients of a plurality of patients, overnight, and when the MRI system is ramped-down; and
dynamically control the at least one component of the plurality of components by automatically adjusting the at least one component of the plurality of components based on scanner state.

14. The method of claim 8, wherein providing the processor comprises further configuring the processor to dynamically control a plurality of subcomponents based optimal energy usage.

15. A method of dynamically controlling a plurality of components of an MRI system by way of an intelligent control system, the method comprising providing the intelligent control system, providing the intelligent control system comprising providing a processor, configurable by a set of executable instructions storable in relation to a non-transient memory device, to:
determine a current-use state of each component of the plurality of components;
optimize energy usage among the plurality of components based on the current-use state of each component of the plurality of components, whereby an optimal energy usage is provided;
alter an energy consumption profile of each component of the plurality of components based on the optimal energy usage, whereby an altered energy consumption for each component of the plurality of components is provided;
automatically activate power to each component of the plurality of components based on the altered energy consumption when the MRI system is to be operated; and
automatically deactivate power to each component of the plurality of components based on the altered energy consumption when the MRI system is not to be operated,
whereby the MRI system is automatically operable when needed and inoperable when not needed, continually powering the plurality of components is eliminated, and an average energy consumption of the MRI system is reduced over its lifespan; and
operating the intelligent control system by using the processor.

16. The method of claim 15, wherein providing the processor comprises configuring the processor to determine the current-use state of each component of the plurality of components comprising at least one of a superconducting electromagnet and an MRI scanner.

17. The method of claim 16, wherein providing the processor comprises configuring the processor to determine the current-use state of each component of the plurality of components further comprising at least one of at least one amplifier, at least one cooling system, and at least one computer.

18. The method of claim 17, wherein providing the processor comprises configuring the processor to determine the current-use state of each component of the plurality of components further comprising the at least one amplifier comprising at least one of a gradient amplifier and a radio-frequency (RF) amplifier.

19. The method of claim 17,
wherein providing the processor comprises configuring the processor to at least one of: disable the at least one amplifier, deactivate the at least one amplifier, switch between different types of amplifiers, switch between different types of power sources, use a low-power source for a low-power scan while a high-power source is warming to avoid delay, change a power consumption mode of the at least one cooling system, change frequency of at least one cooling loop of the at least one cooling system, disable at least one cryogenic cooler of a plurality of cryogenic coolers, cycle the at least one cooling system between activation and deactivation, and place the at last one computer in at least one of a standby mode and a low-power mode,
wherein a low-energy protocol triggers using a low-energy amplifier, and
wherein a high-performance imaging requirement triggers using a combination of a high-power amplifier and a high-power source.

20. The method of claim 19, wherein providing the processor comprises further configuring the processor to at least one of:
dynamically control the at least one component of the plurality of components during at least one of: within a scan, in between scans of a plurality of scans within an examination, in between accommodating patients of a plurality of patients, overnight, and when the MRI system is ramped-down;
dynamically control the at least one component of the plurality of components by automatically adjusting the at least one component of the plurality of components based on scanner state; and
dynamically control a plurality of subcomponents based optimal energy usage.
